(19) United States
(12) Patent Application Publication
(10) Pub. No.: US 2024/0264281 A1
(43) Pub. Date: Aug. 8, 2024

(54) IMAGE SENSING DEVICE

(71) Applicant: SK hynix Inc., Icheon-si (KR)

(72) Inventor: Jae Hyung JANG, Icheon-si (KR)

(21) Appl. No.: 18/408,379

(22) Filed: Jan. 9, 2024

(30) Foreign Application Priority Data
Feb. 2, 2023 (KR) 10-2023-0014424

(51) Int. Cl. G01S 7/481; G01S 17/894; H01L 27/146; H04N 25/77

(52) U.S. Cl. CPC G01S 7/4816; G01S 17/894; H01L 27/14605; H04N 25/77; H04N 25/709

(57) ABSTRACT

An image sensing device includes a pixel array including pixels, each pixel structured to respond to incident light to produce photocharges indicative of detected incident light. The pixel array includes: a first detection structure configured to include a first control node receiving a first demodulation control signal and a first detection node disposed to surround the first control node; a second detection structure configured to include a second control node receiving a second demodulation control signal and a second detection node disposed to surround the second control node; a first storage diode electrically connected to the first detection node; and a second storage diode electrically connected to the second detection node, wherein the first detection structure and the second detection structure are disposed at two opposing vertices of a pixel, respectively, to face each other in a diagonal direction within the pixel.

### CROSS-REFERENCE TO RELATED APPLICATION

This patent document claims the priority and benefits of Korean patent application No. 10-2023-0014424, filed on Feb. 2, 2023, the disclosure of which is incorporated by reference in its entirety as part of the disclosure of this patent document.

### TECHNICAL FIELD

The technology and implementations disclosed in this patent document generally relate to an image sensing device, and more particularly to an image sensing device for sensing a distance to a target object.

### BACKGROUND

An image sensor is a device for capturing at least one image using semiconductor characteristics that react to light incident thereon to produce an image. With the increasing development of computer industries and communication industries, the demand for high-quality and high-performance image sensing devices in, for example, smartphones, digital cameras, game consoles, Internet of Things (IoT), robots, surveillance cameras, medical micro-cameras, etc., has been rapidly increasing.

Image sensors may be broadly classified into CCD (Charge Coupled Device) image sensors and CMOS (Complementary Metal Oxide Semiconductor) image sensors. The CCD image sensors may be superior to the CMOS image sensor in terms of noise and image quality. However, the CMOS image sensor have a simpler and more convenient driving schemes, and thus may be preferred in some applications.

In addition, the CMOS image sensor may integrate a signal processing circuit in a single chip, making it easy to miniaturize the sensors for implementation in a product, with the added benefit of consuming lower power consumption. The CMOS image sensors can be fabricated using a CMOS fabrication technology, which results in low manufacturing cost. The CMOS image sensors have been widely used due to their suitability for implementation in mobile devices.

There have been much developments and studies for measuring range and depth (i.e., a distance to a target object) using image sensors. For example, demand for the above-mentioned depth measurement schemes using image sensors is rapidly increasing in various devices, for example, security devices, medical devices, automobiles, game consoles, virtual reality (VR)/augmented reality (AR) devices, mobile devices, etc. Methods for measuring depth information using one or more image sensors are mainly classified into a triangulation method, a Time of Flight (TOF) method, and an interferometry method. Among above-mentioned depth measurement methods, the Time of Flight (TOF) method from among the above-mentioned depth measurement methods becomes popular because of its wide range of utilization, high processing speed, and cost advantages. The TOF method measures a distance using emitted light and reflected light.

The TOF method may be mainly classified into two different types, i.e., a direct method and an indirect method, depending on whether it is a round-trip time or the phase difference that determines the distance. Although the principles in which the distance (i.e., depth) to a target object is calculated using emitted light and reflected light are commonly applied to the direct method and the indirect method, the direct method and the indirect method may have different measurement methods.

The direct method may calculate a round trip time, and may measure the distance to a target object using the calculated round trip time. The indirect method may measure the distance to the target object using a phase difference. The direct method is suitable for measuring a long-distance measurement, and thus widely used in automobiles. The indirect method is suitable for measuring a short-distance measurement, and thus widely used in various higher-speed devices designed to operate at a higher speed, for example, game consoles, mobile cameras, or others. As compared to the direct type TOF systems, the indirect method has several advantages, including having simpler circuitry, low memory requirement, and a relatively low cost.

A Current-Assisted Photonic Demodulator (CAPD) method is one type of pixel circuitry used in an indirect TOF sensor. In CAPD, electrons are generated in a pixel circuitry by a majority current that is created through an application of a substrate voltage, and the generated electrons are detected by using a difference in potential between electric fields. Since the CAPD method is designed to use the majority current, the CAPD method can more quickly detect electrons. In addition, the CAPD has an excellent efficiency by detecting some electrons formed at a deep depth.

### SUMMARY

Various embodiments of the disclosed technology relate to an image sensing device provided with pixels including an electron detection structure optimized for a smaller-sized product.

In accordance with an embodiment of the disclosed technology, an image sensing device includes a pixel array including pixels, each pixel structured to respond to incident light to produce photocharges indicative of detected incident light. The pixel array includes: a first detection structure configured to include a first control node receiving a first demodulation control signal and a first detection node disposed to surround the first control node; a second detection structure configured to include a second control node receiving a second demodulation control signal and a second detection node disposed to surround the second control node; a first storage diode electrically connected to the first detection node; and a second storage diode electrically connected to the second detection node, wherein the first detection structure and the second detection structure are disposed at two opposing vertices of a pixel, respectively, to face each other in a diagonal direction within the pixel.

In some implementations, the first detection node is connected to the first storage diode through a first storage transistor; and the second detection node is connected to the second storage diode through a second storage transistor.

In some implementations, the first storage diode and the second storage diode are disposed to face each other in a diagonal direction within the pixel.

In some implementations, the pixel array includes a first pixel group including four adjacent pixels including the pixel, wherein the first detection structure and additional first detection structures are disposed at vertices of the first pixel group, and the second detection structure is disposed at a center of the first pixel group.

In some implementations, the first control node and the second control node are configured to generate a current in a substrate, and each of the first detection node and the second detection node is configured to capture photocharges carried by the current.

In some implementations, the first storage diode may temporarily store the photocharges captured by the first detection node, and the second storage diode may temporarily store the photocharges captured by the second detection node.

In some implementations, the pixel may include a first pixel transistor region configured to include a plurality of transistors for processing photocharges captured by the first detection node; and a second pixel transistor region configured to include a plurality of transistors for processing photocharges captured by the second detection node.

In some implementations, the first pixel transistor region and the second pixel transistor region are alternately disposed in the pixel array in the diagonal direction.

In some implementations, the first pixel transistor region and the second pixel transistor region may be disposed at different vertices from the vertices where the first detection structure and the second detection structure are disposed.

In some implementations, the first pixel transistor region may include a first floating diffusion region; and the first floating diffusion region may be disposed at a center of a second pixel group including four adjacent pixels including the pixel, the first floating diffusion region configured to and processes photocharges captured by the first detection node.

In some implementations, the first floating diffusion region may be electrically connected to the first storage diode through a first transfer transistor.

In some implementations, the second pixel transistor region may include a second floating diffusion region; and the second floating diffusion region may be disposed at a center of a third pixel group including four adjacent pixels, the second floating diffusion region configured to process photocharges captured by the second detection node.

In some implementations, the second floating diffusion region may be electrically connected to the second storage diode through a second transfer transistor.

In some implementations, the first detection structure and the second detection structure are alternately disposed in the pixel array in the diagonal direction.

In some implementations, a vertex where the first detection structure is disposed and a vertex where the first detection structure or the second detection structure is not disposed may be alternately disposed in a row direction of the pixel array; or a vertex where the second detection structure is disposed and a vertex where the first detection structure or the second detection structure is not disposed may be alternately disposed in the row direction.

In some implementations, a vertex where the first detection structure is disposed and a vertex where the first detection structure or the second detection structure is not disposed are alternately disposed in a column direction of the pixel array; or a vertex where the second detection structure is disposed and a vertex where the first detection structure or the second detection structure is not disposed are alternately disposed in the column direction.

In accordance with another embodiment of the disclosed technology, an image sensing device is provided to include a pixel structured to convert incident light to a pixel signal; a first detection node and a second detection node disposed to be two opposite sides of the pixel and spaced from each other in a first direction within the pixel; a first storage diode electrically connected to the first detection node; and a second storage diode electrically connected to the second detection node, wherein each of the first detection node and the second detection node is configured to capture photocharges carried by a current generated in a substrate of the pixel; and each of the first storage diode and the second storage diode is configured to temporarily store the photocharges.

In some implementations, the image sensing device sensing device further comprises: a pixel array configured to include pixels that are arranged in rows and columns of a matrix; a control node configured to generate the current in the substrate; and a transistor region configured to include transistors for processing the photocharges, wherein the control node and the transistor region are alternately disposed in a row or column direction of the pixel array.

In some implementations, wherein the control node and additional control nodes are disposed at each of vertices of the pixel and are arranged in the pixel array in the first direction or a second direction perpendicular to the first direction.

In some implementations, wherein the transistor region and additional transistor regions are disposed at each of vertices of the pixel, and are arranged in the pixel array in the first direction or a second direction perpendicular to the first direction.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a pixel array shown in FIG. 1 based on some implementations of the disclosed technology.

FIG. 3 is a schematic diagram illustrating an example of a pixel group included in the pixel array shown in FIG. 2 based on some implementations of the disclosed technology.

FIG. 4 is a cross-sectional view illustrating an example of the pixel group shown in FIG. 3 based on some implementations of the disclosed technology.

FIGS. 5A to 5F are schematic diagrams illustrating examples of an electron detection operation of the image sensing device based on some implementations of the disclosed technology.

FIG. 6 is a circuit diagram illustrating an example of an equivalent circuit diagram of detection nodes configured to share a floating diffusion region based on some implementations of the disclosed technology.

FIG. 7A is a timing diagram illustrating an example of operations of the image sensing device based on some implementations of the disclosed technology.

FIG. 7B is a graph illustrating an example of the principle of calculating a phase difference between modulated light and incident light based on some implementations of the disclosed technology.

FIG. 8 is a schematic diagram illustrating an example of a pixel array based on some other implementations of the disclosed technology.

### DETAILED DESCRIPTION

This patent document provides implementations and examples of image sensing device designs that may be used in configurations to substantially address one or more technical or engineering issues and to mitigate limitations or disadvantages encountered in some other image sensing device designs. Some implementations of the disclosed technology relate to an image sensing device for sensing a distance to a target object. Some implementations of the disclosed technology relate to an image sensing device provided with pixels including an electron detection structure optimized for a smaller-sized product. In recognition of the issues above, the disclosed technology provides the image sensing device having pixels including storage diodes such that a reference signal and an image signal for each pixel can be output as a pixel signal for each pixel. The disclosed technology provides the image sensing device which increases the accuracy of phase difference calculation by calculating image data using the reference signal and the image signal. The disclosed technology provides the image sensing device which collects electrons generated in the substrate by directly applying a voltage to the substrate and thus reduces power consumption by lowering the switching voltage.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

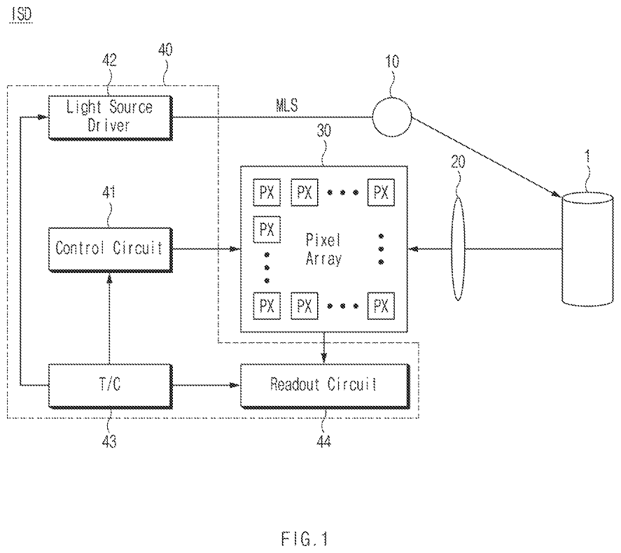

FIG. 1 is a block diagram illustrating an example of an image sensing device ISD based on some implementations of the disclosed technology.

Referring to FIG. 1, the image sensing device ISD may measure the distance to a target object 1 using the Time of Flight (TOF) method. The image sensing device ISD may include a light source 10, a lens module 20, a pixel array 30, and a control module 40.

The light source 10 may emit light to a target object 1 upon receiving a light modulation signal MLS (modulated light signal) from the control module 40. The light source 10 may be a laser diode (LD) or a light emitting diode (LED) for emitting light (e.g., near infrared (NIR) light, infrared (IR) light or visible light) having a specific wavelength band, or may be any one of a Near Infrared Laser (NIR), a point light source, a monochromatic light source combined with a white lamp or a monochromator, and a combination of other laser sources. For example, the light source 10 may emit infrared light having a wavelength of 800 nm to 1000 nm. Light emitted from the light source 10 may be light (i.e., modulated light) modulated by a predetermined frequency. Although FIG. 1 shows only one light source 10 for convenience of description, other implementations are also possible. For example, a plurality of light sources may also be arranged in the vicinity of the lens module 20.

The lens module 20 may collect light reflected from the target object 1, and may allow the collected light to be focused onto pixels (PXs) of the pixel array 30. For example, the lens module 20 may include a focusing lens having a surface formed of glass or plastic or another cylindrical optical element having a surface formed of glass or plastic. The lens module 20 may include a plurality of lenses that is arranged to be focused upon an optical axis.

The pixel array 30 may include unit pixels (PXs) consecutively arranged in a two-dimensional (2D) matrix structure in which unit pixels are arranged in a column direction and a row direction perpendicular to the column direction. The unit pixels (PXs) may be formed over a semiconductor substrate. Each unit pixel (PX) may convert incident light received through the lens module 20 into an electrical signal corresponding to the amount of incident light, and may thus output a pixel signal using the electrical signal. In this case, the pixel signal may not indicate the color of the target object 1, and may be a signal indicating the distance to the target object 1.

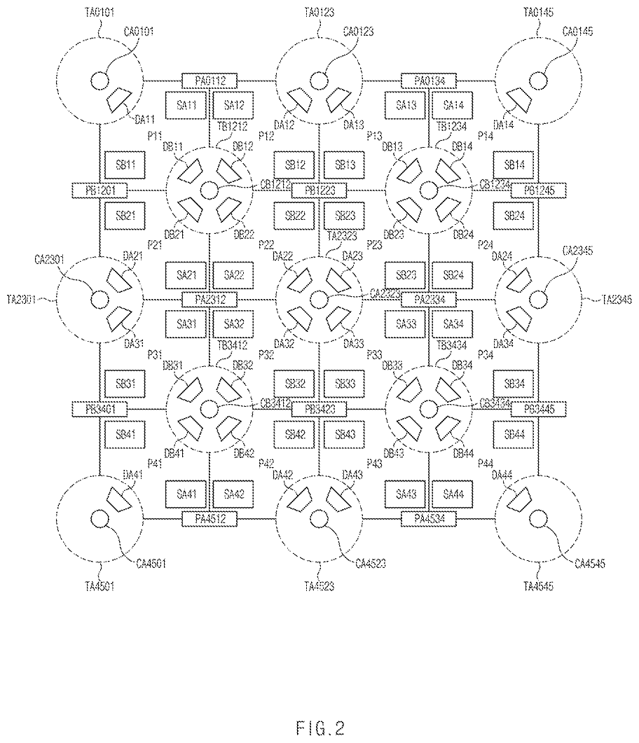

Each unit pixel (PX) may be a Current-Assisted Photonic Demodulator (CAPD) pixel. The structure and operations of each unit pixel (PX) will hereinafter be described with reference to the drawings from FIG. 2.

The unit pixels (PX) may be arranged in a (2×2) matrix to form a pixel group. The pixel group may be a minimum unit in which the same shape is repeatedly arranged in the pixel array.

The control module 40 may emit light to the target object 1 by controlling the light source 10, may process each pixel signal corresponding to light reflected from the target object 1 by driving unit pixels (PXs) of the pixel array 30, and may measure the distance to the surface of the target object 1 using the processed result.

The control module 40 may include a control circuit 41, a light source driver 42, a timing controller 43, and a readout circuit 44.

The control circuit 41 may drive unit pixels (PXs) of the pixel array in response to a timing signal generated from the timing controller 43. For example, the control circuit 41 may generate a control signal capable of selecting and controlling at least one row line from among the plurality of row lines. The control signal may include a demodulation control signal for generating a hole current in the substrate, a reset signal for controlling a reset transistor, a transmission (Tx) signal for controlling transmission of photocharges accumulated in a detection node, a floating diffusion (FD) signal for providing additional electrostatic capacity at a high illuminance level, a selection signal for controlling a selection transistor, and the like.

Although FIG. 1 illustrates the control circuit 41 arranged in a column direction (i.e., a vertical direction) of the pixel array 30 for convenience of description, at least some parts (e.g., a circuit for generating a demodulation control signal) of the control circuit 41 may be arranged in a row direction (i.e., a horizontal direction) of the pixel array 30.

The control circuit 41 may receive a signal from the timing controller 43, and may transmit driving signals including a row selection signal, a pixel reset signal, and a transmission signal to the pixel array 30. A unit pixel included in the pixel array 30 may be activated to perform the operations corresponding to the driving signals.

In more detail, the control circuit 41 may generate a row selection signal to select one or more rows among the plurality of rows, and may sequentially enable the pixel reset signal and the transmission signal for the unit pixels corresponding to the at least one selected row. Thus, a reference signal and an image signal, which are analog signals generated from each of the imaging pixels of the selected row, may be output from each pixel of the selected row.

The light source driver 42 may generate a light modulation signal MLS capable of driving the light source 10 in response to a control signal from the timing controller 43. The light modulation signal MLS may be a signal that is modulated by a predetermined frequency.

The timing controller 43 may generate a timing signal to control the control circuit 41, the light source driver 42, and the readout circuit 44.

The readout circuit 44 may process pixel signals received from the pixel array 30 under control of the timing controller 43, and may thus generate pixel data formed in a digital signal shape. To this end, the readout circuit 44 may include a correlated double sampler (CDS) circuit for performing correlated double sampling on the pixel signals generated from the pixel array 30.

In some implementations, the correlated double sampler (CDS) circuit may sequentially receive a reference signal indicating an electrical signal that is provided to the CDS circuit when a sensing node (e.g., a floating diffusion node) is reset, and an image signal indicating an electrical signal that is provided to the CDS circuit when photocharges generated by the unit pixels are accumulated in the sensing node.

The reference signal indicating unique reset noise of each pixel and the image signal indicating the intensity of incident light may be collectively referred to as a pixel signal as necessary.

The correlated double sampler (CDS) circuit may remove undesired offset values of pixels known as the fixed pattern noise by sampling a pixel signal twice to remove the difference between these two samples. In more detail, the correlated double sampler (CDS) circuit may compare pixel output voltages obtained before and after photocharges generated by incident light received in the unit pixels are accumulated in the sensing node so that only pixel output voltages based on the incident light can be measured.

The CDS circuit may sequentially sample and hold voltage levels of the reference signal and the image signal, which are provided to each of a plurality of column lines included in the pixel array 110.

In addition, the readout circuit 44 may include an analog-to-digital converter (ADC) for converting output signals of the CDS circuit into digital signals. In addition, the readout circuit 44 may include a buffer circuit that temporarily stores pixel data generated from the analog-to-digital converter (ADC) and outputs the pixel data under control of the timing controller 43. In the meantime, since the pixel array 30 includes CAPD pixels, two column lines for transmitting the pixel signal may be assigned to each column of the pixel array 30, and structures for processing the pixel signal generated from each column line may be configured to correspond to the respective column lines.

The light source 10 may emit light (i.e., modulated light) modulated by a predetermined frequency to a scene captured by the image sensing device ISD. The image sensing device ISD may sense modulated light (i.e., incident light) reflected from the target objects 1 included in the scene, and may thus generate depth information for each unit pixel (PX).

A time delay based on the distance between the image sensing device ISD and each target object 1 may occur between the modulated light and the incident light. The time delay may be denoted by a phase difference between the signal generated by the image sensing device ISD and the light modulation signal MLS controlling the light source 10. An image processor (not shown) may calculate a phase difference generated in the output signal of the image sensing device ISD, and may thus generate a depth image including depth information for each unit pixel (PX).

FIG. 2 is a schematic diagram illustrating an example of the pixel array 30 shown in FIG. 1 based on some implementations of the disclosed technology.

Referring to FIG. 2, one example of the pixel array 30 is illustrated. Although FIG. 2 illustrates 16 unit pixels arranged in a matrix including four rows and four columns for convenience of description, other implementations are also possible. Thus, the pixel array 30 can include other suitable number of unit pixels as necessary or desired for a specific sensing application.

Each of the unit pixels may be denoted by Pnm (where each of ‘n’ and ‘m’ is an arbitrary positive number). In this case, ‘n’ means a row including the corresponding pixel, and ‘m’ means a column including the corresponding pixel. For example, the pixel P11 may be a pixel belonging to a first row and a first column as shown on the left-upper corner in the pixel array in FIG. 2.

Meanwhile, a number representing each of a row disposed at an upper side of the first row and a column disposed at a left side of the first column will hereinafter be defined as zero ‘0’. In addition, a number representing a row disposed at a lower side of the fourth row will hereinafter be defined as 5, and a number representing a column disposed at a right side of the fourth column will hereinafter be defined as 5.

The pixel array 30 may include first taps (e.g., first tap TA2323 located near the center of FIG. 2) and second taps (e.g., second tap TB1212 located near the upper-left side of the first tap TA2323) that are arranged in the pixel array. Each tap is a detection structure that includes a control node configured to receive a control signal and a plurality of detection nodes disposed adjacent to the control node to collect and detect photocharges. As shown in FIG. 2, the first and second taps are located at intersections of the unit pixels and are spatially interleaved with the unit pixels. For example, first tap TA2323 is located at the intersection of adjacent unit pixels P22, P23, P33 and P32, and second tap TB1212 is located at the intersection of adjacent unit pixels P11, P12, P22 and P21. The first tap TA2323 and second tap TB1212 are located at two opposing vertices of unit pixel P22 as shown in FIG. 2.

Each of the first taps may be disposed at the center of four pixels arranged in a (2×2) matrix, and each of the second taps may be disposed at the center of four pixels arranged in a (2×2) matrix. A structure in which four pixels are arranged in the (2×2) matrix may be referred to as a pixel group.

For example, the first tap TA2323 may be disposed at the center of the pixels P22, P23, P32, and P33, and the second tap TB1212 may be disposed at the center of the pixels P11, P12, P21, and P22.

The first tap or the second tap may be referred to as Txy, where ‘x’ indicates the type of a tap (e.g., the first tap is denoted by ‘A’ or the second tap is denoted by ‘B’) and ‘y’ indicates the position of a tap (e.g., the tap denoted by TA2323 is arranged at the center of pixels P22, P23, P32, and P33 corresponding to an intersection of pixels belonging to the second row and the third row and other pixels belonging to the second column and the third column).

In some implementations, an exemplary case in which a certain structure is disposed at the center of four pixels may conceptually include not only one case in which the center of the corresponding structure (e.g., the first tap) is identical to the center of the four pixels, but also the other case in which a portion of the corresponding structure overlaps with the center of the four pixels.

In some implementations, a pixel group in which the second tap is disposed at the center of the four pixels may be referred to as a first pixel group. A first tap may be disposed at each of four vertices of the first pixel group.

A unit pixel included in the pixel array 30 may be formed in a quadrangular shape, and may include four vertices that are respectively disposed at an upper-left side, an upper-right side, a lower-left side, and a lower-right side of each unit pixel. In addition, the unit pixel may include four corners (edges) that are respectively disposed at the upper-left side, the upper-right side, the lower-left side, and the lower-right side of each unit pixel.

For convenience of description and better understanding of the disclosed technology, the vertex disposed at the upper-left side of each pixel will hereinafter be referred to as a first vertex, the vertex disposed at the upper-right side of each pixel will hereinafter be referred to as a second vertex, the vertex disposed at the lower-left side of each pixel will hereinafter be referred to as a third vertex, and the vertex disposed at the lower-right side of each pixel will hereinafter be referred to as a fourth vertex. A first tap and a second tap may be respectively disposed at two vertices (e.g., the first and fourth vertices, or the second and third vertices) that face each other in a diagonal direction in each pixel. Here, a diagonal direction from the first vertex to the fourth vertex will hereinafter be referred to as a first diagonal direction, and a diagonal direction from the second vertex to the third vertex will hereinafter be referred to as a second diagonal direction. Assuming that a first tap and a second tap are disposed in a first diagonal direction in a particular pixel, the first tap and the second tap can be arranged in a second diagonal direction in pixels adjacent to upper, lower, left, and right sides of the particular pixel.

Accordingly, the first taps and the second taps may be alternately disposed in the first diagonal direction or the second diagonal direction within the pixel array 30. For example, the second tap TB1212, the first tap TA2323, and the second tap TB3434 may be alternately disposed in a first diagonal direction with respect to the first tap TA0101.

In some implementations, the first taps or the second taps may be sparsely disposed in a row direction (or a horizontal direction) or a column direction (or a vertical direction) of the pixel array 30 without being disposed at consecutive vertices. For example, a vertex where the first tap or the second tap is disposed in the row direction (or horizontal direction) or the column direction (or vertical direction) and a vertex where the first tap or the second tap is not disposed in the row or column direction may be alternately arranged. In some examples, the first taps are arranged along the row direction or the column direction at vertex regions that are not consecutive in the row direction or the column direction. The second taps are arranged along the row direction or the column direction at vertex regions that are not consecutive in the row direction or the column direction.

A first pixel transistor region (e.g., PA0112) or a second pixel transistor region (e.g., PB1223) may be alternately disposed at a vertex where the first tap or the second tap is not disposed. The first pixel transistor region or the second pixel transistor region may be sparsely disposed in a row direction (or a horizontal direction) or a column direction (or a vertical direction) of the pixel array 30 without being disposed at consecutive vertices.

The first tap or the second tap may include a control node and a plurality of detection nodes surrounding the control node. The detection nodes are adjacent to the control node. Although each of the control nodes shown in FIG. 2 is formed in a circular shape and each of the detection nodes shown in FIG. 2 is formed in a trapezoidal shape for convenience of description, other implementations are also possible.

In the disclosed technology, a control node and each of the detection nodes included in the first tap will hereinafter be referred to as a first control node and a first detection node, respectively. A control node and each of the detection nodes included in the second tap will hereinafter be referred to as a second control node and a second detection node.

The first control node CA2323 included in the first tap (e.g., TA2323) may be surrounded by four first detection nodes DA22, DA23, DA32, and DA33. In addition, the second control node CB1212 included in the second tap (e.g., TB1212) may be surrounded by four second detection nodes DB11, DB12, DB21, and DB22.

Each of the detection nodes shown in FIG. 2 may be formed in a trapezoidal shape. For example, the detection node may be formed in a trapezoidal shape in which a length of one side contiguous or adjacent to the control node surrounded by the detection node is shorter than a length of the other side arranged to face the one side. Such trapezoidal shape of the detection nodes may help each of the detection nodes in a tap to surround the control node in the tap as much as possible. Thus, the area of the control node surrounded by the detection nodes can increase with the trapezoidal shape of the detection nodes. The trapezoidal shape of each of the detection nodes may help to capture signal carriers, which migrate in the direction of a charge current (e.g., a hole current) caused by each of the control nodes. Thus, the signal carriers can be more easily captured with the detection nodes.

The control node may be disposed at the center (or at the vertex region(s) of each pixel) of the pixel group in which four unit pixels construct a (2×2) matrix array. The detection nodes may be arranged to face each other in a first or second direction with respect to the control node. In addition, each of the detection nodes may be partially included in four pixels contiguous or adjacent to each of the control nodes.

One unit pixel may include one first detection node and one second detection node.

For example, the first tap TA2323 may be disposed at the center of the pixels P22, P23, P32, and P33. The first detection nodes DA22, DA23, DA32, and DA33 included in the first tap TA2323 may be respectively included in the pixels P22, P23, P32, and P33. The second tap TB1212 may be disposed at the center of the pixels P11, P12, P21, and P22. The second detection nodes DB11, DB12, DB21, and DB22 included in the second tap TB1212 may be respectively included in the pixels P11, P12, P21, and P22. In this case, one unit pixel P22 may include one first detection node DA22 and one second detection node DB22.

The control nodes receive different voltages. The hole current flowing between the control nodes may increase in proportion to a potential difference between the control nodes, may increase in inverse proportion to the distance between the control nodes, and may increase in proportion to the size of each of sides of the control nodes that face to each other. Thus, the hole current flowing between the control nodes receiving different voltages may decrease in inverse proportion to a potential difference between the control nodes, may decrease in proportion to the distance between the control nodes, and may decrease in inverse proportion to the size of each of sides of the control nodes that face to each other.

The hole current may be determined by a potential difference between the control nodes and resistance between the control nodes. The resistance between the control nodes may increase in proportion to the distance between the control nodes, and may also increase in inverse proportion to the size of each of the sides of the control nodes that face to each other.

In some implementations, the unit pixels arranged in a (2×2) matrix to construct the pixel group may share a control node, and each pixel may independently include a detection node. For example, the pixels P22, P23, P32, P33 arranged in a 2×2 matrix share the control node CA2323 disposed at the center of the 2×2 matrix and include the respective detection nodes DA22, DA23, DA32, DA33. As the pixels arranged in the (2×2) matrix share the control node, the distance between the control nodes within any pixel can maximally increase, which results in reduction in the magnitude of hole current.

In addition, as the pixels constructing the pixel group share the control node, the number of control nodes required in the pixel array 30 is reduced to ¼ as compared to the case where each pixel includes its own control node.

As the number of control nodes decreases, load of the control circuit 41 can be greatly reduced, and power consumption of the image sensing device can also be greatly reduced.

A unit pixel (e.g., P11) disposed in the pixel array 30 may include a first storage element region (e.g., SA11) and a second storage element region SB11.

The first storage element region may be a region including a first storage diode connected to the first detection node. In some implementations, the first detection node and the first storage diode may be connected to each other through a first storage transistor, and the first storage transistor may be disposed in the first storage element region.

In some implementations, the first storage element region may further include a first global reset transistor configured to reset the first detection node and the first storage transistor.

The second storage element region may be a region including a second storage diode connected to the second detection node. In some implementations, the second detection node and the second storage diode may be connected to each other through a second storage transistor, and the second storage transistor may be disposed in the second storage element region.

In some implementations, the second storage element region may further include a second global reset transistor configured to reset the second detection node and the second storage transistor.

Within a unit pixel, the first storage element region and the second storage element region may be disposed to face each other in the first direction or the second direction. In addition, a direction in which the first storage element region and the second storage element region are disposed to face each other may be perpendicular to a direction in which the first detection node and the second detection node are disposed to face each other.

For example, the first storage element region SA11 and the second storage element region SB11 included in the unit pixel P11 may be disposed to face each other in the second direction along which a second vertex (i.e., an upper-right vertex) of the unit pixel P11 is connected to a third vertex (i.e., a lower-left vertex) of the unit pixel P11.

In this case, the second direction may be perpendicular to the first direction along which the first vertex (i.e., the upper-left vertex) of the unit pixel P11 is connected to the fourth vertex (i.e., the lower-right vertex) of the unit pixel P11, and the first detection node DA11 and the second detection node DB11 may be disposed to face each other in the first direction.

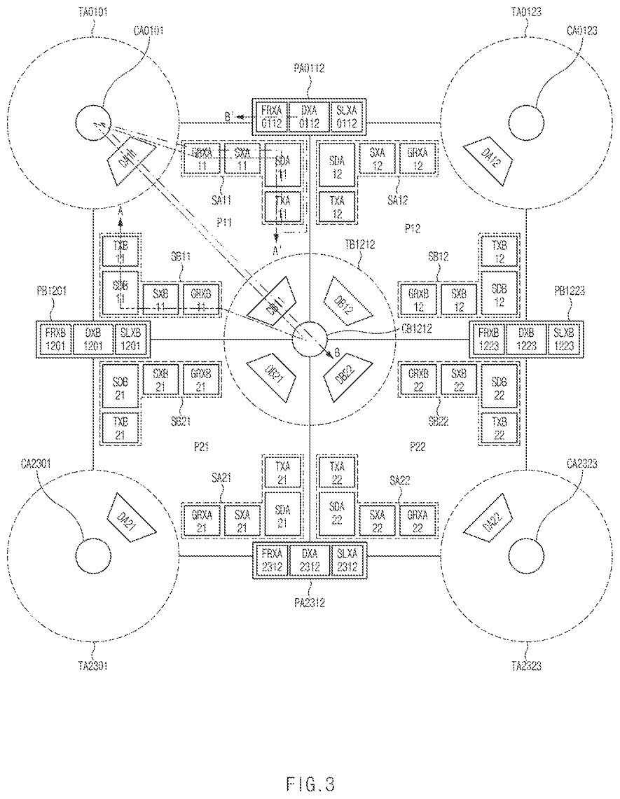

Shapes and arrangement relationships of storage transistors, storage diodes, and global reset transistors included in the first diode region and the second diode region will be described in detail with reference to FIG. 3.

The first pixel transistor region (e.g., PA2312) disposed in the pixel array 30 may be disposed at the center of four pixels (e.g., P21, P22, P31, and P32) arranged in an arbitrary (2×2) matrix. In some implementations, four pixels arranged in a (2×2) matrix such that the first pixel transistor region is located at the center of the four pixels may be referred to as a second pixel group.

The second pixel transistor region (e.g., PB1223) disposed in the pixel array 30 may be disposed at the center of four pixels (e.g., P12, P13, P22, and P23) arranged in an arbitrary (2×2) matrix. In some implementations, four pixels arranged in a (2×2) matrix such that the second pixel transistor region is located at the center of four pixels may be referred to as a third pixel group.

The first pixel transistor region or the second pixel transistor region may include a plurality of pixel transistors.

The pixel transistor may be a transistor for processing a pixel signal output from a unit pixel. For example, the first pixel transistor region or the second pixel transistor region may include a drive transistor, a selection transistor, and a floating diffusion reset transistor. In addition, the pixel transistor region may include a floating diffusion region in which photocharges from adjacent detection nodes are accumulated.

The pixel transistors included in the first pixel transistor region and the floating diffusion region may be shared by unit pixels of a second pixel group. Similarly, the pixel transistors and the floating diffusion region included in the second pixel transistor region may be shared by unit pixels of a third pixel group.

The floating diffusion region may accumulate photocharges, and the pixel array 30 may output a pixel signal based on a voltage signal corresponding to the accumulated photocharges. The readout circuit 44 may generate pixel data by processing the output pixel signals.

A floating diffusion region included in the first pixel transistor region may be referred to as a first floating diffusion region. The first floating diffusion region may be connected to four first storage diodes included in the second pixel group.

A floating diffusion region included in the second pixel transistor region may be referred to as a second floating diffusion region. The second floating diffusion region may be connected to four second storage diodes included in the third pixel group.

Shapes and arrangement relationships of pixel transistors included in the first pixel transistor region and the second pixel transistor region will be described in detail with reference to FIG. 3.

As described above, in the pixel array 30, the first pixel transistor region or the second pixel transistor region may be alternately disposed at vertices where the first tap or the second tap is not disposed.

The first pixel transistor region or the second pixel transistor region may be sparsely disposed in a row direction (or a horizontal direction) or a column direction (or vertical direction) in the pixel array 30. In addition, the first pixel transistor regions and the second pixel transistor regions may be alternately disposed in the first diagonal direction or the second diagonal direction.

FIG. 3 is a schematic diagram illustrating an example of the pixel group included in the pixel array shown in FIG. 2 based on some implementations of the disclosed technology.

A layout structure of the first pixel group is illustrated in detail through FIG. 3. In the example of FIG. 3, the first pixel group includes four unit pixels (P11, P12, P21, P22). As discussed above, the pixel group in which the second tap is disposed at the center of the four pixels may be referred to as a first pixel group.

A second tap TB1212 may be disposed at the center of the first pixel group, and first taps (TA0101, TA0123, TA2301, TA2323) may be respectively disposed at vertices of the first pixel group.

The first pixel transistor region PA0112 may be disposed at the upper edge of the first pixel group, and the first pixel transistor region PA2312 may be disposed at the lower edge of the first pixel group. In addition, the second pixel transistor region PB1201 may be disposed at the left edge of the first pixel group, and the second pixel transistor region PB1223 may be disposed at the right edge of the first pixel group.

In the unit pixel P11, the first storage element region SA11 may include a first global reset transistor GRXA11, a first storage transistor SXA11, a first storage diode SDA11, and a first transfer transistor TXA11.

The first detection node DA11 may be connected to the first storage diode SDA11 through the first storage transistor SXA11, and the first transfer transistor TXA11 may connect the first storage diode SDA11 to the first floating diffusion region included in the first pixel transistor PA0112. The connections above may refer to the electric connections between the elements.

The second storage element region SB11 may include a second global reset transistor GRXB11, a second storage transistor SXB11, a second storage diode SDB11, and a second transfer transistor TXB11.

The second detection node DB11 may be electrically connected to the second storage diode SDB11 through the second storage transistor SXB11, and the second storage diode SDB11 may be electrically connected to the second floating diffusion region included in the second pixel transistor region PB1201 through the second transfer transistor TXB11.

The detection node may capture photocharges by a hole current flowing by an electric field generated inside a pixel.

The storage transistor may transfer photocharges captured through the detection node to the storage diode. The storage diode may temporarily store photocharges. The transfer transistor may transfer photocharges from the storage diode to the floating diffusion region.

The global reset transistor may reset photocharges in a unit pixel before the unit pixel receives light. Since the reset transistor resets photocharges, a signal corresponding to incident light can be more accurately measured, such that the accuracy of a pixel signal obtained through the correlated double sampling (CDS) operation can be increased.

The first pixel transistor region PA0112 may include a first floating diffusion region, a first drive transistor DXA0112, a first floating diffusion reset transistor FRXA0112, and a first selection transistor SLXA0112. The first drive transistor DXA0112 may be electrically connected to the first floating diffusion region to amplify an electric potential of the first floating diffusion region. The first floating diffusion reset transistor FRXA0112 may be electrically connected to the first floating diffusion region to reset the first floating diffusion region. The first selection transistor SLXA0112 may be configured to selectively output a voltage amplified by the first drive transistor DXA0112.

The second pixel transistor region PB1201 may include a second floating diffusion region, a second drive transistor DXB1201, a second floating diffusion reset transistor FRXB1201, and a second selection transistor SLXB1201. The second drive transistor DXB1201 may be electrically connected to the second floating diffusion region to amplify a voltage of the second floating diffusion region. The second floating diffusion reset transistor FRXB1201 may be electrically connected to the second floating diffusion region to reset the second floating diffusion region. The second selection transistor SLXB1201 may be configured to selectively output a voltage amplified by the second drive transistor DXB1201.

Elements included in the first pixel transistor region (e.g., a first floating diffusion region, a first floating diffusion reset transistor, a first drive transistor, and a first selection transistor) may be shared by four adjacent unit pixels.

In the examples, elements included in the second pixel transistor region (e.g., the second floating diffusion region, the second floating diffusion reset transistor, the second drive transistor, and the second selection transistor) may be shared by four unit pixels.

Four unit pixels adjacent to the first pixel transistor region may be unit pixels included in a second pixel group in which the first pixel transistor region is located at the center of the second pixel group. In addition, the four unit pixels adjacent to the second pixel transistor region may be unit pixels included in a third pixel group in which the second pixel transistor region is located at the center of the third pixel group.

By sharing the elements included in the pixel transistor region, it is possible to secure a region for forming elements. In addition, a design margin for improving element characteristics can be secured.

For example, a region for forming the floating diffusion node can be secured by allowing the unit pixels to share the floating diffusion region, thereby securing the capacity of the floating diffusion node. In addition, operating characteristics and noise characteristics of the transistors can be improved by sufficiently securing the areas of the 5 drive transistor and the selection transistor.

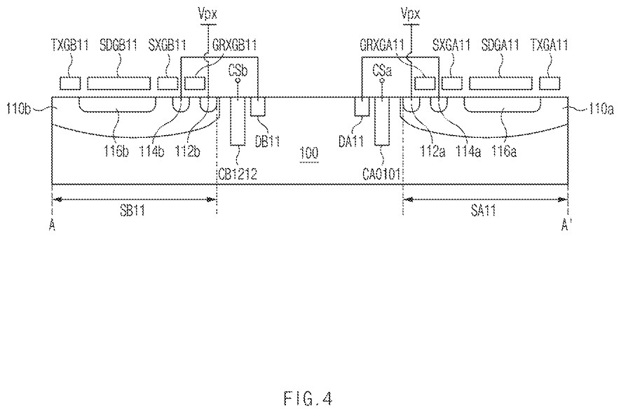

FIG. 4 is a cross-sectional view illustrating an example of the unit pixel P11 taken along a first cutting line shown in FIG. 3 based on some implementations of the disclosed technology.

FIG. 4 is a cross-sectional view illustrating the unit pixel P11 taken along the first cutting line A-A′ shown in FIG. 3.

Referring to FIG. 4, the pixel P11 may include a substrate region 100 included in the pixel P11, and a plurality of transistor gates (TXGB11, SDGB11, SXGB11, GRXGB11, TXGA11, SDGA11, SXGA11, GRXGA11) disposed to overlap the substrate region 100. Although the pixel P11 is described as an example in FIG. 4, a pixel included in the pixel array 30 may have substantially the same structure and operation as the pixel P11.

The substrate region 100 may include a first control node CA0101, a second control node CB1212, a first detection node DA11, and a second detection node DB11.

In the examples, the substrate region 100 may include a plurality of impurity regions. The impurity regions may include, for example, a first well region 110a, a first global reset transistor region 112a, a first storage transistor region 114a, a first storage diode region 116a, a second well region 110b, a second global reset transistor region 112b, a second storage transistor region 114b, and a second storage diode region 116b.

The substrate region 100 may be or include a photoelectric conversion region in which photocharges corresponding to incident light are generated. In some implementations, the substrate region 100 may be a P-type semiconductor substrate.

The plurality of transistor gates (TXGB11, SDGB11, SXGB11, GRXGB11, TXGA11, SDGA11, SXGA11, GRXGA11) may be separated 10 from the substrate region 100 by an interlayer insulation layer (not shown).

The plurality of transistor gates (TXGB11, SDGB11, SXGB11, GRXGB11, TXGA11, SDGA11, SXGA11, GRXGA11) may be gates of elements included in the storage element regions (SA11, SB11).

For example, the global reset transistor gates (GRXGA11, GRXGB11) may be gates of the global reset transistors (GRXA11, GRXB11), and the storage transistor gates (SXGA11, SXGB11) may be gates of the storage transistors (SXA11, SXB11).

In the examples, the storage diode gates (SDGA11, SDGB11) may be gates of the storage diodes (SDA11, SDB11), and the transfer transistor gates (TXGA11, TXGB11) may be gates of the transfer transistors (TXA11, TXB11).

The global reset transistors (GRXA11, GRXB11) may reset the unit pixel P11 according to a signal applied to the global reset transistor gates (GRXGA11, GRXGA11).

The storage transistors (SXA11, SXB11) may transfer photocharges received from the detection nodes (DA11, DB11) to the 5 storage diodes (SDA11, SDB11) according to signals applied to the storage transistor gates (SXGA11, SXGB11).

The potentials of the storage diodes (SDA11, SDB11) may vary according to signals applied to the storage diode gates (SDGA11, SDGB11).

The transfer transistors (TXA11, TXB11) may transfer photocharges from the storage diodes (SDA11, SDB11) to a floating diffusion region (not shown) according to a signal applied to the transfer transistor gates (TXGA11, TXGB11).

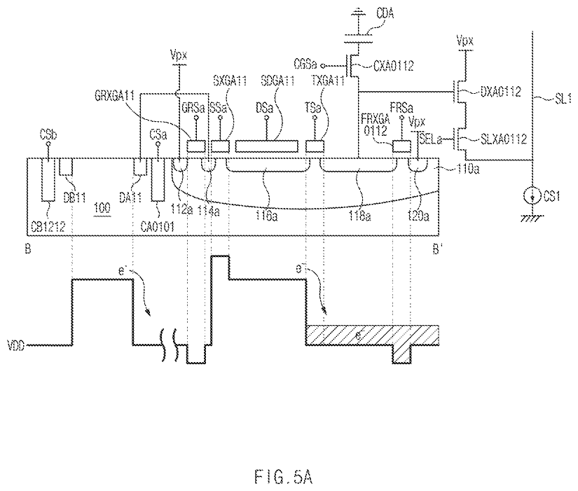

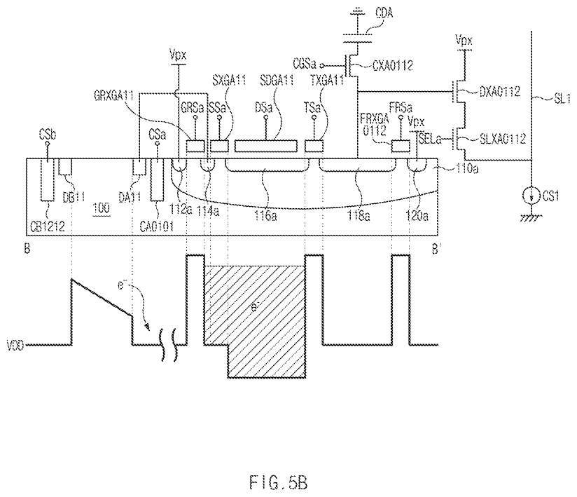

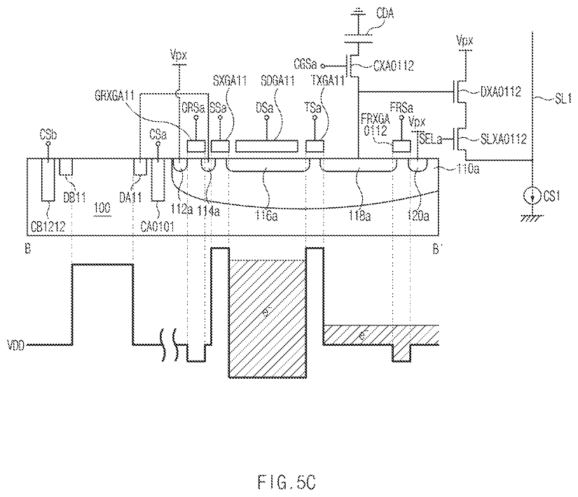

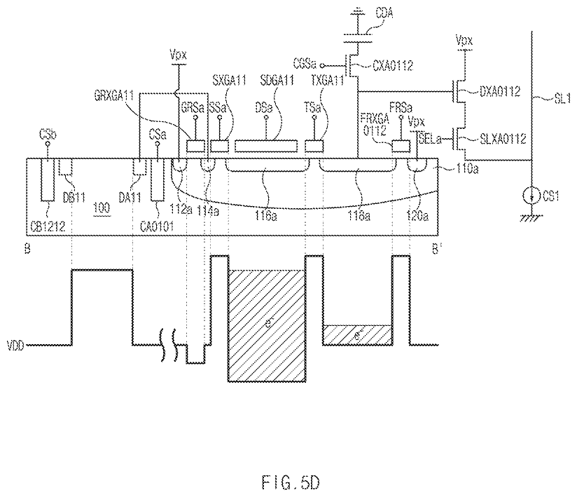

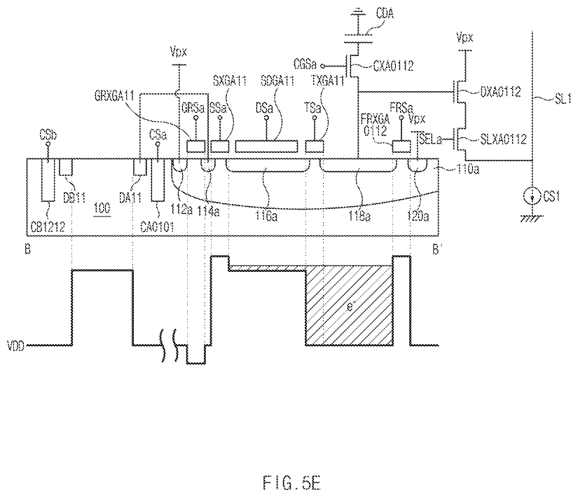

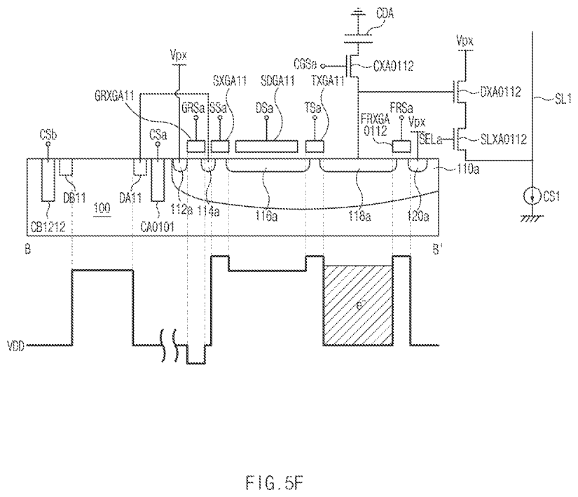

A method for operating elements included in the unit pixel P11 and a potential change according to a signal applied to gate(s) will hereinafter be described in detail with reference to FIGS. 5A to 5F.

Each of the elements (e.g., transistors or diodes) included in the storage element region may include a gate and an impurity region. In some implementations, elements of the storage element region may be or include metal oxide semiconductor field effect transistors (MOSFETs) or diodes, and the impurity region may construct a portion of source or drain regions of each transistor or a portion of each diode.

The first control node CA0101 and the second control node CB1212 that are formed inside the substrate region 100 may be P-type impurity regions. The first detection node DA11 and the second detection node DB11 that are formed inside the substrate region 100 may be N-type impurity regions.

In some implementations, the first control node CA0101 and the second control node CB1212 may include P-type impurity regions having different doping concentrations. For example, the P-type impurity region (e.g., P⁻ region) having a relatively low doping concentration may be implanted into the substrate region 100 to a first depth, and the P-type impurity region (e.g., P⁺ region) having a relatively high doping concentration may be implanted into the substrate region 100 to a second depth at the same position as the above P⁻-type impurity implantation position. In this case, the first depth may be greater than the second depth.

The first detection node DA11 and the second detection node DB11 may include N-type impurity regions having different doping concentrations. For example, the N-type impurity region (e.g., N⁻ region) having a relatively low doping concentration may be implanted into the substrate region 100 to a third depth, and the N-type impurity region (e.g., N⁺ region) having a relatively high doping concentration may be implanted into the substrate region 100 to a fourth depth at the same position as the above N⁻-type impurity implantation position. In this case, the first depth may be greater than the third depth.

The first and second control nodes CA0101 and CB1212 and the first and second detection nodes DA11 and DB11 may be physically separated from each other.

The first control node CA0101 may receive a first control signal (CSa) from the control circuit 41, and the second control node CB1212 may receive a second control signal (CSb) from the control circuit 41. A potential difference between the first control signal (CSa) and the second control signal (CSb) may generate an electric field (or a hole current) that controls flow of photocharges (or signal carriers) generated in the substrate by incident light.

As the first control node CA0101 and the second control node CB1212 directly apply a voltage to the substrate, electrons generated inside the substrate can be easily collected and the switching voltage can be reduced. As the switching voltage is lowered, power consumption of the image sensing device can be reduced.

Each of the first and second detection nodes (DA11, DB11) may capture photocharges and accumulate the captured photocharges. Elements connected to the first and second detection nodes (DA11, DB11) may process photocharges captured by the first and second detection nodes (DA11, DB11), and may convert the processed photocharges into electrical signals. The elements may be disposed in the storage element regions (SA11, SB11) and the pixel transistor region.

According to a potential difference between the first control signal CSa and the second control signal CSb that are respectively applied to the first control node CA0101 and the second control node CB1212, a time point at which the first detection node DA11 collects charges and a time point at which the second detection node DB11 collects charges may become different from each other. Thus, the first control signal (CSa) and the second control signal (CSb) may be demodulation signals having different phase differences, and a charge collection period of the first detection node DA11 and a charge collection period of the second detection node DB11 may vary depending on a phase difference between the first control signal (CSa) and the second control signal (CSb).

In some implementations, the first control signal (CSa) and the second control signal (CSb) may be signals having opposite phases (or a phase difference of 180 degrees (n)). As the first control signal (CSa) has the same phase as the modulated light signal (MLS), the first control signal (CSa) and the modulated light signal (MLS) may also have the same phase.

The first control signal (CSa) and the second control signal (CSb) may be sinusoidal signals having either an activation voltage (also called an active voltage) or a deactivation voltage (also called an inactive voltage) at a preset cycle. The activation voltage and the deactivation voltage may be experimentally determined. For example, the activation voltage may be set to 1.2 V, and the deactivation voltage may be zero volts (OV).

The first detection node DA11 may be electrically connected to the first global reset transistor GRXA11 and the first storage transistor SXA11 through a conductive line. Thus, the first detection node DA11 may be electrically connected to the first storage transistor region 114a through a conductive line.

The second detection node DB11 may be electrically connected to the second global reset transistor GRXB11 and the second storage transistor SXB11 through a conductive line. Thus, the second detection node DB11 may be electrically connected to the second storage transistor region 114b through a conductive line.

Each of the storage element regions SA11 and SB11 may include a plurality of elements. The elements may overlap the substrate region 100, and at least a portion of the elements may be disposed inside the substrate region 100. The storage element region SA11 may include a global reset transistor GRXA11, a storage transistor SXA11, a storage diode SDA11, and a transfer transistor TXA11. The storage element region SB11 may include a global reset transistor GRXB11, a storage transistor SXB11, a storage diode SDB11, and a transfer transistor TXB11. The plurality of elements included in each of the storage element regions SA11 and SB11 may include impurity regions, and a gate corresponding to each element may be included in the storage element regions SA11 and SB11.

Hereinafter, impurity regions included in the storage element regions SA11 and SB11 will be described in detail with reference to the drawings.

The first global reset transistor region 112a, the first storage transistor region 114a, and the first storage diode region 116a may be disposed in a first well region 110a, and doped with impurities having a conductivity type different from that of the first well region 110a.

The second global reset transistor region 112b, the second storage transistor region 114b, and the second storage diode region 116b may be disposed in a second well region 110b, and doped with impurities having a conductivity type different from that of the second well region 110b.

For example, the first well region 110a and the second well region 110b may be doped with the same P-type impurity as the substrate region 100. The global reset transistor regions (112a, 112b), the storage transistor regions (114a, 114b), and the storage diode regions (116a, 116b) may be regions doped with N-type impurities.

The global reset transistor regions (112a, 112b), the storage transistor regions (114a, 114b), or the storage diode regions (116a, 116b) may be source or drain regions of the global reset transistors (GRXA11, GRXB11), the storage transistors (SXA11, SXB11), or the transfer transistors (TXA11, TXB11). In the examples, the global reset transistor region 112a, the storage transistor region 114a, or the storage diode region 116a may be source or drain regions of the global reset transistor GRXA11, the storage transistor SXA11, or the transfer transistor TXA11. The global reset transistor region 112b, the storage transistor region 114b, or the storage diode region 116b may be source or drain regions of the global reset transistor GRXB11, the storage transistor SXB11, or the transfer transistor TXB11.

The global reset transistors (GRXA11, GRXB11), the storage transistors (SXA11, SXB11), and the transfer transistors (TXA11, TXB11) may control movement of photocharges among the global reset transistor regions (112a, 112b), the storage transistor regions (114a, 114b) and the storage diode regions (116a, 116b) according to signals applied to gates thereof.

The photocharges captured by the first detection node DA11 may be transferred to the first storage transistor region 114a through a conductive line. The first storage transistor region 114a may transfer photocharges to the first storage diode region 116a according to a signal applied to the first storage transistor gate SXGA11, or may be reset to a predetermined potential level according to a signal applied to the first global reset transistor gate GRXGA11. A voltage at which the first storage transistor region 114a is reset may be referred to as a pixel voltage (Vpx), and the pixel voltage may be a power-supply voltage (VDD) or a source voltage (VSS).

Similarly, the photocharges captured by the second detection node DB11 may be transferred to the second storage transistor region 114b through a conductive line. The second storage transistor region 114b may transfer photocharges to the second storage diode region 116b according to a signal applied to the second storage transistor gate SXGB11, or may be reset to a predetermined potential level according to a signal applied to the second global reset transistor gate GRXGB11. The second storage transistor region 114b may also be reset to the pixel voltage (Vpx).

FIGS. 5A to 5F are schematic diagrams illustrating examples of an electron detection operation of the image sensing device based on some implementations of the disclosed technology.

FIGS. 5A to 5F are cross-sectional views illustrating the pixel group taken along a second cutting line B-B′ shown in FIG. 3 based on some implementations of the disclosed technology. In addition, FIGS. 5A to 5F illustrate examples of signals applied to elements included in the unit pixel P11, and also illustrates a potential change caused by signals applied to the elements of the unit pixel P11 for description of the movement of photocharges.

The cross-sectional view of the pixel taken along the second cutting line B-B′ of FIG. 3 partially overlaps the cross-sectional view of the pixel taken along the first cutting line A-A′ of FIG. 3, and as such redundant description thereof will herein be omitted for brevity.

The substrate region 100 may include a first floating diffusion region 118a that is connected to the first storage diode region 116a through the first transfer transistor TXA11.

The first floating diffusion region 118a may be disposed in the first well region 110a, and may be doped with impurities having a conductivity type different from that of the first well region 110a. For example, the first floating diffusion region 118a may be a region doped with N-type impurities. The first floating diffusion region 118a may receive photocharges, and store the photocharges.

The first floating diffusion region 118a may be connected to the first floating diffusion reset transistor FRXA0112. The first floating diffusion reset transistor FRXA0112 may include a first floating diffusion reset transistor gate FRXGA0112 and a first floating diffusion reset transistor gate region 120a.

The first floating diffusion reset transistor FRXA0112 may reset the first floating diffusion region 118a to the pixel voltage (Vpx) according to the first floating diffusion reset signal (FRSa).

The first floating diffusion region 118a may be connected to the first capacitor CDA by the first capacitive transistor CXA0112. The first capacitor CDA may be selectively connected to the first floating diffusion region 118a according to operations of the first capacitive transistor CXA0112 so as to provide additional predetermined capacitance. The first capacitor CDA may include, for example, at least one of a Metal-Insulator-Metal (MIM) capacitor, a Metal-Insulator-Polysilicon (MIP) capacitor, a Metal-Oxide-Semiconductor (MOS) capacitor, and a junction capacitor.

The first floating diffusion region 118a may be connected to a gate electrode of the first drive transistor DXA0112. A drain electrode of the first drive transistor DXA0112 is connected to the pixel voltage (Vpx) and a source electrode of the first drive transistor DXA0112 is connected to a vertical signal line SL1 through the first selection transistor SLXA0112, such that a load (MOS) and a source follower circuit of a constant current source circuit CS1 coupled to one end of the vertical signal line SL1 can be constructed. Thus, the first drive transistor DXA0112 may output a current corresponding to potential of the first floating diffusion region 118a coupled to a gate electrode thereof to the vertical signal line SL1 through the first selection transistor SLXA0112.

The first selection transistor SLXA0112 may be activated in response to a logic high level of the first selection signal (SELa) supplied to a gate electrode thereof, so that the first selection transistor SLXA0112 can transmit the pixel signal received from the first drive transistor DXA0112 to the vertical signal line SL1.

FIG. 5A is a schematic diagram illustrating an example operation for globally resetting the unit pixel P11 before the first detection node DA11 captures photocharges.

When the image sensing device ISD performs global resetting, the first global reset transistor GRXA11 may be activated in response to a logic high level of the first global reset control signal (GRSa) supplied to the first global reset transistor gate GRXGA11.

When the first global reset transistor GRXA11 is activated, the photocharges remaining in the first detection node DA11 move to the first global reset transistor region 112a through the first storage transistor region 114a, so that the first detection node DA11 and the first storage transistor region 114a may be reset to the power-supply voltage (VDD).

When the image sensing device ISD performs such global reset, the first transfer transistor TXA11 may be activated in response to the logic high level of the first transfer signal (TSa) supplied to the first transfer transistor gate TXGA11. In addition, the first floating diffusion reset transistor FRXA0112 may be activated in response to the logic high level of the first floating diffusion reset signal (FRSa) supplied to the first floating diffusion reset transistor gate FRXGA0112.

When the first transfer transistor TXA11 is activated, photocharges remaining in the first storage diode region 116a may move to the first floating diffusion region 118a. The photocharges moved to the first floating diffusion region 118a may move to the first floating diffusion reset region 120a through the first floating diffusion reset transistor FRXA0112. Through the above operation, the first storage diode region 116a and the first floating diffusion region 118a may be reset to the power-supply voltage (VDD).

FIG. 5B is a schematic diagram illustrating an example operation in which the first detection node DA11 captures photocharges.

When the pixel PX11 receives incident light, photocharges corresponding to the incident light may be generated within the substrate region 100 by the photoelectric effect.

According to the potential difference between the control signals applied to the first control node CA0101 and the second control node CB1212, a hole current that controls flow of photocharges may occur in the substrate region 100, and the photocharges can move by the hole current.

The first detection node DA11 or the second detection node DB11 may perform a function of capturing and accumulating photocharges.

FIG. 5B illustrates a timing point at which the first control signal (CSa) having an activation voltage is applied to the first control node CA0101, and a timing point at which the second control signal (CSb) having a deactivation voltage is applied to the second control node CB1212.

Referring to FIG. 5B, when the first control signal (CSa) having an activation voltage is applied to the first control node CA0101 and the second control signal (CSb) having a deactivation voltage is applied to the second control node CB1212, a hole current may flow from the second control node CB1212 to the first control node CA0101. In this case, photocharges generated in the substrate region 100 may move to the first detection node DA11.

When the first control signal (CSa) having an activation voltage is applied to the first control node CA0101 and the second control signal (CSb) having a deactivation voltage is applied to the second control node CB1212, the potential of the first control node CA0101 may be lower than that of the second control node CB1212, and photocharges may be accumulated in the first detection node DA11 adjacent to the first control node CA0101.

When the first detection node DA11 accumulates photocharges, the first storage transistor SXA11 may be activated in response to a logic high level of the first storage signal (SSa) supplied to the gate SXGA11.

When the first storage transistor SXA11 is activated, photocharges accumulated by the first detection node DA11 may move to the first storage diode region 116a via the first storage transistor region 114a.

In this case, the first activation signal (DSa) applied to the first storage diode gate SDGA11 formed to overlap the first storage diode region 116a may have a logic high value.

As the first active signal (DSa) has a logic high value, the storage capacity of the first storage diode region 116a can be increased.

FIG. 5C is a schematic diagram illustrating an example operation in which the first floating diffusion region 118a is reset to output the first reference signal.

In order to output the first reference signal, the first global reset transistor GRXA11 may be activated in response to a logic high level of the first global reset control signal (GRSa) supplied to the first global reset transistor gate GRXGA11.

When the first global reset transistor GRXA11 is activated, the photocharges remaining in the first detection node DA11 move to the first global reset transistor region 112a through the first storage transistor region 114a, such that the first detection node DA11 and the first storage transistor region 114a can be reset to the power-supply voltage (VDD).

In addition, the first floating diffusion reset transistor FRXA0112 may be activated in response to a logic high level of the first floating diffusion reset signal (FRSa) supplied to the first floating diffusion reset transistor gate FRXGA0112.

When the first floating diffusion reset transistor FRXA0112 is activated, photocharges in the first floating diffusion region 118a may move to the first floating diffusion reset region 120a. Through the above operation, the first floating diffusion region 118a may be reset to the power-supply voltage (VDD).

At this time, the first storage transistor SXA11 and the first transfer transistor TXA11 may be in a deactivation state (inactive state).

The first floating diffusion region 118a may be reset to the power-supply voltage VDD, so that the first floating diffusion region 118a can output a first reference signal.

FIG. 5D is a schematic diagram illustrating an example operation for outputting the first reference signal.

In operation of outputting the first reference signal, the first storage transistor SXA11, the first transfer transistor TXA11, and the first floating diffusion reset transistor FRXA11 may be deactivated.

The first drive transistor DXA0112 may amplify a current corresponding to potential of the first floating diffusion region 118a connected to a gate electrode thereof.

The first selection transistor SLXA0112 connected to the first drive transistor DXA0112 may output a first reference signal to the first vertical signal line SL1 in response to the first selection signal (SELa).

After resetting the first floating diffusion region 118a, the first drive transistor DXA0112 may amplify the current corresponding to potential of the first floating diffusion region 118a, so that a first reference signal corresponding to offset noise generated by a circuit structure, etc. of the unit pixel P11 can be output as a pixel signal.

FIG. 5E is a schematic diagram illustrating an example operation for transferring photocharges of the first storage diode region 116a to the first floating diffusion region 118a so as to output a first image signal.

In order to output the first image signal, the first transfer transistor TXA11 may be activated in response to a logic high level of the first transfer signal (TSa) supplied to the first transfer transistor gate TXGA11.

When the first transfer transistor TXA11 is activated, photocharges temporarily stored in the first storage diode region 116a may move to the first floating diffusion region 118a. The first floating diffusion region 118a may store the received photocharges.

The photocharges may generate a potential in the first floating diffusion region 118a, and the first drive transistor DXA0112 may amplify a current corresponding to potential of the first floating diffusion region 118a connected to a gate electrode thereof.

The first activation signal (DSa) may have a logic low value so that photocharges can be easily transferred from the first storage diode 10 region 116a to the first floating diffusion region 118a. As the first storage diode gate SDGA11 is activated, the potential of the first storage diode region 116a may increase. Accordingly, photocharges can easily move from the first storage diode region 116a to the first floating diffusion region 118a having a relatively low potential.

In some implementations, the first floating diffusion region 118a may be connected to the first capacitor CDA by the first capacitive transistor CXA0112.

The first capacitor CDA may be selectively connected to the first floating diffusion region 118a according to operation of the first capacitive transistor CXA0112 so as to provide a predetermined capacitance.

For example, when the image sensing device ISD operates in a high-illuminance operating environment, photocharges exceeding the capacity of the first floating diffusion region 118a may be transferred. When the first floating diffusion region 118a is saturated, an accurate pixel signal may not be output, so that the first capacitive transistor CXA0112 may be activated to increase capacitance of the first floating diffusion region 118a.

FIG. 5F is a schematic diagram illustrating an example operation for outputting the first image signal.

In operation of outputting the first image signal, the first storage transistor SXA11, the first transfer transistor TXA11, and the first floating diffusion reset transistor FRXA11 may be deactivated.

The first drive transistor DXA0112 may amplify a current corresponding to potential of the first floating diffusion region 118a connected to a gate electrode thereof.

The first selection transistor SLXA0112 connected to the first drive transistor DXA0112 may output the first image signal to the first vertical signal line SL1 in response to the first selection signal (SELa).

The photocharges received from the first storage diode region 116a may generate a potential in the first floating diffusion region 118a, and the first drive transistor DXA0112 may amplify the current corresponding to the potential so that the first image signal corresponding to incident light received by the pixel P11 can be output as a pixel signal.

Although the above embodiments have been described for the first detection node DA11, the elements connected to the second detection node DB11 can also operate in the similar manner, while different voltages are applied to the control nodes CA0101 and CB1212 in the photocharge capture operation. Accordingly, a second reference signal and a second image signal may be output as pixel signals from the elements connected to the second detection node DB11 through a second vertical signal line (not shown).

The image sensing device ISD may remove an offset value of the first image signal using the first reference signal and the first image signal that are sequentially output through the first vertical signal line SL1, and may thus convert the first image signal into first image data through analog-to-digital conversion (ADC) processing. In addition, the offset value of the second image signal may be removed using the second reference signal and the second image signal that are sequentially output through the second vertical signal line, and may thus convert the second image signal into second image data through ADC processing.

An image processor (not shown) included in the image sensing device ISD may calculate first image data obtained from the first detection node DA11 and second image data obtained from the second detection node DB11, and may thus calculate a phase difference based on the calculated result.

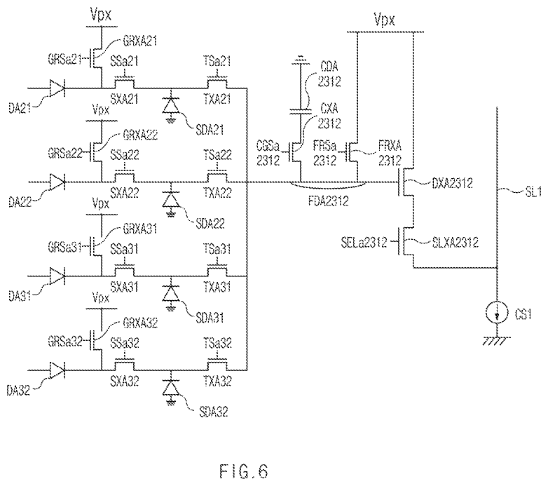

FIG. 6 is a circuit diagram illustrating an example of an equivalent circuit diagram of detection nodes configured to share a floating diffusion region based on some implementations of the disclosed technology.

The equivalent circuit diagram of FIG. 6 may be an equivalent circuit diagram of four unit pixels (P21, P22, P31, P32) sharing the first floating diffusion region FDA2312 included in the first pixel transistor region PA2312 of FIG. 1. FIG. 6 illustrates an equivalent circuit of elements connected to the first detection nodes (DA21, DA22, DA31, DA32) respectively included in the four unit pixels (P21, P22, P31, P32).

The first detection nodes (DA21, DA22, DA31, DA32) may collect photocharges from the substrate regions of the unit pixels (P21, P22, P31, P32). In more detail, the first detection node DA21 may collect photocharges from the substrate region of the unit pixel P21, the first detection node DA22 may collect photocharges from the substrate region of the unit pixel P22, the first detection node DA31 may collect photocharges from the substrate region of the unit pixel P31, and the first detection node DA32 may collect photocharges from the substrate region of the unit pixel P32.

The first detection nodes (DA21, DA22, DA31, DA32) may be connected to the first global reset transistors (GRXA21, GRXA22, GRXA31, GRXA32). In more detail, the first detection node DA21 may be connected to the first global reset transistor GRXA21, the first detection node DA22 may be connected to the first global reset transistor GRXA22, the first detection node DA31 may be connected to the first global reset transistors GRXA31, and the first detection node DA32 may be connected to the first global reset transistor GRXA32.

The first global reset transistors (GRXA21, GRXA22, GRXA31, GRXA32) may allow the first detection nodes (DA21, DA22, DA31, DA32) to be reset to a predetermined potential level (e.g., pixel voltage Vpx) according to logic levels of the first global reset signals (GRSa21, GRSa22, GRSa31, GRSa32). In more detail, the first global reset transistor GRXA21 may allow the first detection node DA21 to be reset to a predetermined potential level such as the pixel voltage (Vpx) according to a logic level of the first global reset signal GRSa21, the first global reset transistor GRXA22 may allow the first detection node DA22 to be reset to a predetermined potential level such as the pixel voltage (Vpx) according to a logic level of the first global reset signal GRSa22, the first global reset transistor GRXA31 may allow the first detection node DA31 to be reset to a predetermined potential level such as the pixel voltage (Vpx) according to a logic level of the first global reset signal GRSa31, and the first global reset transistor GRXA32 may allow the first detection node DA32 to be reset to a predetermined potential level such as the pixel voltage (Vpx) according to a logic level of the first global reset signal GRSa32.

The first detection nodes (DA21, DA22, DA31, DA32) may be connected to the first storage diodes (SDA21, SDA22, SDA31, SDA32) through the first storage transistors (SXA21, SXA22, SXA31, SXA32). In more detail, the first detection node DA21 may be connected to the first storage diode SDA21 through the first storage transistor SXA21, the first detection node DA22 may be connected to the first storage diode SDA22 through the first storage transistor SXA22, the first detection node DA31 may be connected to the first storage diode SDA31 through the first storage transistor SXA31, and the first detection node DA32 may be connected to the first storage diode SDA32 through the first storage transistor SXA32.

The first storage transistors (SXA21, SXA22, SXA31, SXA32) may transmit the photocharges of the first detection nodes (DA21, DA22, DA31, DA32) to the first storage diodes (SDA21, SDA22, SDA31, SDA32) according to logic levels of the first storage signals (SSa21, SSa22, SSa31, SSa32). In more detail, the first storage transistor SXA21 may transmit the photocharges of the first detection node DA21 to the first storage diode SDA21 according to a logic level of the first storage signal SSa21, the first storage transistor SXA22 may transmit the photocharges of the first detection node DA22 to the first storage diode SDA22 according to a logic level of the first storage signal SSa22, the first storage transistor SXA31 may transmit the photocharges of the first detection node DA31 to the first storage diode SDA31 according to a logic level of the first storage signal SSa31, and the first storage transistor SXA32 may transmit the photocharges of the first detection node DA32 to the first storage diode SDA32 according to a logic level of the first storage signal SSa32.

The first storage diodes (SDA21, SDA22, SDA31, SDA32) may be connected to the first floating diffusion node FDA2312 through the first transfer transistors (TXA21, TXA22, TXA31, TXA32). In more detail, the first storage diode SDA21 may be connected to the first floating diffusion node FDA2312 through the first transfer transistor TXA21, the first storage diode SDA22 may be connected to the first floating diffusion node FDA2312 through the first transfer transistor TXA22, the first storage diode SDA31 may be connected to the first floating diffusion node FDA2312 through the first transfer transistor TXA31, and the first storage diode SDA32 may be connected to the first floating diffusion node FDA2312 through the first transfer transistor TXA32.

The first transfer transistors (TXA21, TXA22, TXA31, TXA32) may transmit the photocharges of the first storage diodes (SDA21, SDA22, SDA31, SDA32) to the first floating diffusion node FDA2312 according to logic levels of the first transfer signals (TSa21, TSa22, TSa31, TSa32). In more detail, the first transfer transistor TXA21 may transmit the photocharges of the first storage diode SDA21 to the first floating diffusion node FDA2312 according to a logic level of the first transfer signal TSa21, the first transfer transistor TXA22 may transmit the photocharges of the first storage diode SDA22 to the first floating diffusion node FDA2312 according to a logic level of the first transfer signal TSa22, the first transfer transistor TXA31 may transmit the photocharges of the first storage diode SDA31 to the first floating diffusion node FDA2312 according to a logic level of the first transfer signal TSa31, and the first transfer transistor TXA32 may transmit the photocharges of the first storage diode SDA32 to the first floating diffusion node FDA2312 according to a logic level of the first transfer signal TSa32.

The first floating diffusion node FDA2312 may be connected to four first storage diodes (SDA21, SDA22, SDA31, SDA32). In other words, the four first storage diodes (SDA21, SDA22, SDA31, SDA32) may share one first floating diffusion node FDA2312.

Since the first floating diffusion node FDA2312 is shared by the four adjacent unit pixels (P21, P22, P31, P32), the degree of freedom of a pixel layout structure can be improved.

The first floating diffusion node FDA2312 may be connected to the first capacitor CDA2312 through the first capacitive transistor CXA2312. The capacitance of the first floating diffusion node FDA2312 may be controlled according to the first capacitance signal CGSa2312 applied to the first capacitive transistor CXA2312.

In addition, the first floating diffusion node FDA2312 may be connected to one side of the first floating diffusion reset transistor FRXA2312. The other side of the first floating diffusion reset transistor FRXA2312 may be connected to the pixel voltage (Vpx).

The first floating diffusion reset transistor FRXA2312 may allow the first floating diffusion node FDA2312 to be reset to the pixel voltage (Vpx) according to the logic level of the first floating diffusion reset signal FRSa2312.

The first floating diffusion node FDA2312 may be connected to the gate of the first drive transistor DXA2312. The first drive transistor DXA2312 may be connected to a load (MOS) of the constant current source circuit unit CS1 through the first selection transistor SLXA2312, resulting in formation of a source follower circuit.

The first drive transistor DXA2312 may amplify a current corresponding to potential of the first floating diffusion node FDA2312, and may output the amplified current to the first vertical signal line SL1 through the first selection transistor SLXA2312.

The first selection transistors SLXA2312 disposed at the same position in the row direction on the pixel array 30 may share the same first selection signal line, and the first selection signal SELa2312 can be applied through the first selection signal line.

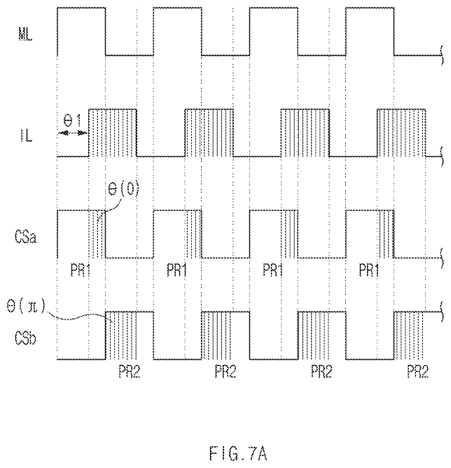

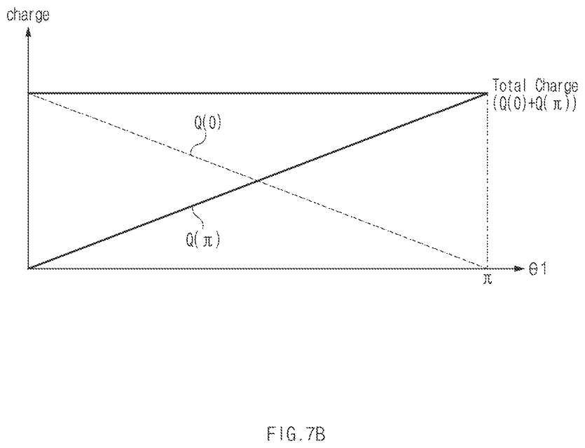

FIG. 7A is a timing diagram illustrating an example of operations of the image sensing device based on some implementations of the disclosed technology.

FIG. 7B is a graph illustrating an example of the principle of calculating a phase difference between modulated light and incident light based on some implementations of the disclosed technology.

The image sensing device ISD of the disclosed technology may operate using a two-phase (2-phase) modulation scheme.

FIG. 7A exemplarily illustrates modulated light (ML), incident light (IL), the first demodulation control signal (CSa), and the second demodulation control signal (CSb). For convenience of description, the first control signal (CSa) may be applied to the first control node CA0101 included in the pixel P11, and the second control signal (CSb) may be applied to the second control node CB1212.

The modulated light (ML) may refer to light that is emitted to the target object 1 by the light source 10 controlled by the control module 40. The modulated light (ML) may be generated to alternately have a high-level section (i.e., a period in which light is emitted) and a low-level section (i.e., a period in which light is not emitted).

The incident light (IL) may refer to light that is incident upon the substrate to generate electron-hole pairs through photoelectric conversion. The incident light (IL) may have a phase difference (01) that is changed with the distance between the image sensing device ISD and the target object 1.

The level of each of the modulated light (ML) and the incident light (IL) may refer to the intensity of light.

While electrons generated by the incident light (IL) are captured, each of the first control signal (CSa) and the second control signal (CSb) may alternately have a deactivation voltage indicating a low level and an activation voltage indicating a high level. In addition, the first control signal (CSa) may have the same phase as the modulated light (ML), and the second control signal (CSb) may have a phase opposite to that of the modulated light (ML) (i.e., a phase difference of 180° (π) with respect to the modulated light ML).

In some implementations, it is assumed that no phase difference occurs between the light modulation signal MLS generating the modulated light (ML) and the modulated light (ML) for convenience of description, such that the light modulation signal MLS and the modulated light (ML) may have the same phase.

In a first period PR1, the first control signal (CSa) may have the activation voltage (H), and the second control signal (CSb) may have the deactivation voltage (L). Therefore, electrons generated by incident light (IL) received in the first period PR1 may move toward the first tap by a hole current, such that the electrons can be captured by the first detection node DA11. In this case, the electrons captured by the first detection node DA11 in the first period PR1 may hereinafter be denoted by “Q(0)”.

In a second period PR2, the first control signal (CSa) may have the deactivation voltage, and the second demodulation control signal (CSb) may have the activation voltage. Therefore, electrons generated by incident light (IL) received in the second period PR2 may move toward the second tap TB1212 by a hole current, such that the electrons can be captured by the second detection node DB11. In this case, the electrons captured by the second detection node DB11 in the second period PR2 may hereinafter be denoted by “Q(π)”.

Thus, electrons generated by the incident light (IL) having a phase difference (01) that is changed with the distance between the image sensing device ISD and the target object 1, may be captured by the first detection node DA11 in the first period PR1, and may be captured by the second detection node DB11 in the second period PR2.

Referring to FIG. 7B, a graph indicating the relationship between the phase difference (θ1) and the detected electrons Q(0) and Q(n) is shown. In the graph of FIG. 7B, an X-axis may represent the amount of charges, and a Y-axis may represent a phase difference.

The total charge generated by the incident light IL may be defined as the sum of Q(0) and Q(n). As the phase difference increases, Q(n) may linearly increase and Q(0) may linearly decrease. Therefore, the phase difference (θ1) can be calculated based on the ratio between Q(0) and Q(n).

For example, the phase difference (θ1) may be calculated as represented by the following equation 1.

$$θ1 = π \cdot \frac{Q ( π )}{Q ( 0 ) + Q ( π )} \qquad [ Equation 1 ]$$

An image processor (not shown) may calculate the ratio between Q(0) and Q(n) based on first image data corresponding to Q(0) captured in the first period PR1 and second image data corresponding to Q(n) captured in the second period PR2. Here, the first image data and the second image data may be received from the pixel P11. Thereafter, the image processor may calculate a phase difference based on the calculated ratio, and may thus obtain the distance between the image sensing device ISD and the target object 1.

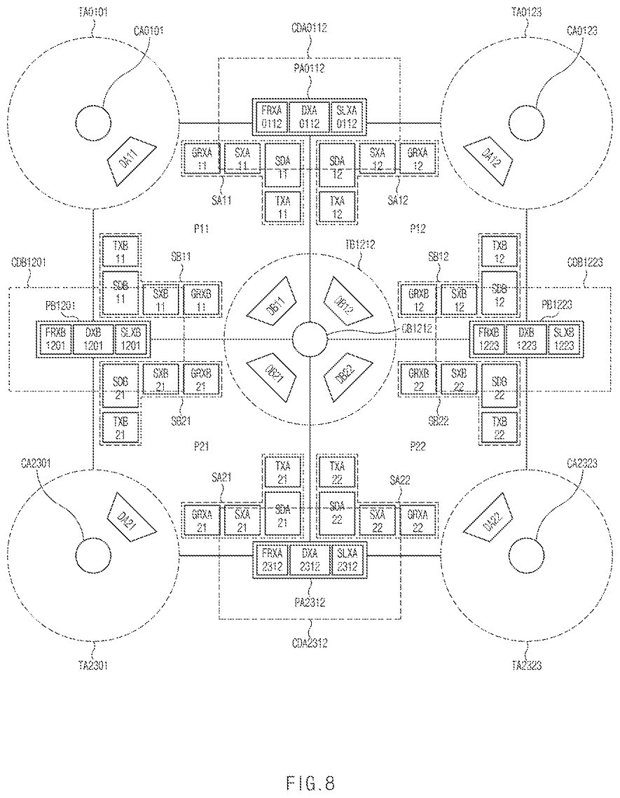

FIG. 8 is a schematic diagram illustrating an example of a pixel array based on some other implementations of the disclosed technology.

FIG. 8 illustrates capacitors (e.g., CDA0112), each of which overlaps pixel transistor regions (e.g., PA0112).

As described above, the capacitors may be connected to the floating diffusion region (or floating diffusion node) through a capacitive transistor, and may provide additional capacitance to the floating diffusion region according to the operating environment of the image sensing device ISD.

The capacitors may be implemented as metal-insulator-metal (MIM) capacitors, and may be disposed in a different layer from pixel transistors. Thus, the capacitors can be disposed to overlap the pixel transistor region, so that the degree of freedom of the layout structure can be secured. In addition, the capacitors are arranged as described above, so that additional capacitance of the floating diffusion region can be secured.

As is apparent from the above description, since pixels of the image sensing device based on some implementations of the disclosed technology include storage diodes, a reference signal and an image signal for each pixel can be output as a pixel signal for each pixel.

The image sensing device based on some implementations of the disclosed technology may increase the accuracy of phase difference calculation by calculating image data using the reference signal and the image signal.

The image sensing device based on some implementations of the disclosed technology may collect electrons generated in the substrate by directly applying a voltage to the substrate, and thus reduce power consumption by lowering the switching voltage.

The embodiments of the disclosed technology may provide a variety of effects capable of being directly or indirectly recognized through the above-mentioned patent document.

Although a number of illustrative embodiments have been described, it should be understood that modifications and/or enhancements to the disclosed embodiments and other embodiments can be devised based on what is described and/or illustrated in this patent document.

What is claimed is:

1. An image sensing device comprising:
a pixel array including pixels, each pixel structured to respond to incident light to produce photocharges indicative of detected incident light,
wherein the pixel array includes:
a first detection structure configured to include a first control node receiving a first demodulation control signal and a first detection node disposed to surround the first control node;
a second detection structure configured to include a second control node receiving a second demodulation control signal and a second detection node disposed to surround the second control node;
a first storage diode electrically connected to the first detection node; and
a second storage diode electrically connected to the second detection node,
wherein
the first detection structure and the second detection structure are disposed at two opposing vertices of a pixel, respectively, to face each other in a diagonal direction within the pixel.

2. The image sensing device according to claim 1, wherein:
the first detection node is connected to the first storage diode through a first storage transistor; and
the second detection node is connected to the second storage diode through a second storage transistor.

3. The image sensing device according to claim 1, wherein:
the first storage diode and the second storage diode are disposed to face each other in another diagonal direction within the pixel.

4. The image sensing device according to claim 1, wherein the pixel array includes a first pixel group including four adjacent pixels including the pixel, and
wherein the first detection structure and additional first detection structures are disposed at vertices of the first pixel group, and
the second detection structure is disposed at a center of the first pixel group.

5. The image sensing device according to claim 1, wherein:
the first control node and the second control node are configured to generate a current in a substrate; and
each of the first detection node and the second detection node is configured to capture photocharges carried by the current.

6. The image sensing device according to claim 5, wherein:
the first storage diode is configured to temporarily store the photocharges captured by the first detection node; and
the second storage diode is configured to temporarily store the photocharges captured by the second detection node.

7. The image sensing device according to claim 1, wherein the pixel includes:
a first pixel transistor region configured to include a plurality of transistors for processing photocharges captured by the first detection node; and
a second pixel transistor region configured to include a plurality of transistors for processing photocharges captured by the second detection node.

8. The image sensing device according to claim 7,
wherein the first pixel transistor region and the second pixel transistor region are alternately disposed in the pixel array in the diagonal direction.

9. The image sensing device according to claim 8, wherein:
the first pixel transistor region and the second pixel transistor region are disposed at different vertices from the vertices where the first detection structure and the second detection structure are disposed.

10. The image sensing device according to claim 8, wherein:
the first pixel transistor region includes a first floating diffusion region; and
the first floating diffusion region is disposed at a center of a second pixel group including four adjacent pixels including the pixel, the first floating diffusion region configured to process photocharges captured by the first detection node.

11. The image sensing device according to claim 10, wherein:
the first floating diffusion region is electrically connected to the first storage diode through a first transfer transistor.

12. The image sensing device according to claim 8, wherein:
the second pixel transistor region includes a second floating diffusion region; and
the second floating diffusion region is disposed at a center of a third pixel group including four adjacent pixels, the second floating diffusion region configured to process photocharges captured by the second detection node.

13. The image sensing device according to claim 12, wherein:
the second floating diffusion region is electrically connected to the second storage diode through a second transfer transistor.

14. The image sensing device according to claim 1,
wherein the first detection structure and the second detection structure are alternately disposed in the pixel array in the diagonal direction.

15. The image sensing device according to claim 14, wherein:
a vertex where the first detection structure is disposed and a vertex where the first detection structure or the second detection structure is not disposed are alternately disposed in a row direction of the pixel array; or
a vertex where the second detection structure is disposed and a vertex where the first detection structure or the second detection structure is not disposed are alternately disposed in the row direction.

16. The image sensing device according to claim 14, wherein:
a vertex where the first detection structure is disposed and a vertex where the first detection structure or the second detection structure is not disposed are alternately disposed in a column direction of the pixel array; or
a vertex where the second detection structure is disposed and a vertex where the first detection structure or the second detection structure is not disposed are alternately disposed in the column direction.

17. An image sensing device comprising:
a pixel structured to convert incident light to a pixel signal;
a first detection node and a second detection node disposed to be two opposite sides of the pixel and spaced from each other in a first direction within the pixel;
a first storage diode electrically connected to the first detection node; and
a second storage diode electrically connected to the second detection node,
wherein
each of the first detection node and the second detection node is configured to capture photocharges carried by a current generated in a substrate of the pixel; and
each of the first storage diode and the second storage diode is configured to temporarily store the photocharges.

18. The image sensing device according to claim 17, further comprising:
a pixel array configured to include pixels that are arranged in rows and columns of a matrix;
a control node configured to generate the current in the substrate; and
a transistor region configured to include transistors for processing the photocharges,
wherein
the control node and the transistor region are alternately disposed in a row or column direction of the pixel array.

19. The image sensing device according to claim 18, wherein:
the control node and additional control nodes are disposed at each of vertices of the pixel, and are arranged in the pixel array in the first direction or a second direction perpendicular to the first direction.

20. The image sensing device according to claim 18, wherein:
the transistor region and additional transistor regions are disposed at each of vertices of the pixel, and are arranged in the pixel array in the first direction or a second direction perpendicular to the first direction.
